(19) United States
(12) Patent Application Publication
(10) Pub. No.: US 2014/0204544 A1
(43) Pub. Date: Jul. 24, 2014

(54) FLAT WIRING MEMBER AND MANUFACTURING METHOD THEREOF

(71) Applicant: Hitachi Metals, Ltd., Tokyo (JP)

(72) Inventors: Kotaro Tanaka, Naka (JP); Toshiyuki Horikoshi, Mito (JP); Takumi Sato, Hitachi (JP); Kenichi Murakami, Hitachi (JP)

(73) Assignee: Hitachi Metals, Ltd., Tokyo (JP)

(21) Appl. No.: 14/158,331

(22) Filed: Jan. 17, 2014

(30) Foreign Application Priority Data
Jan. 24, 2013 (JP) 2013-010852

(51) Int. Cl. H05K 1/11; H05K 3/30

(52) U.S. Cl. CPC H05K 1/11; H05K 3/30
USPC 361/752; 361/748; 29/825

(57) ABSTRACT

A flat wiring member and a manufacturing method thereof are provided which are capable of suppressing an increase in thickness of the flat wiring member even if a circuit element is connected to the flat wiring member and simplifying a manufacturing process of the flat wiring member. A flat wiring member includes a plurality of conductors disposed on a plane to be spaced from one another and one or more circuit elements connected to one or more of the plurality of conductors. Each of the conductors connected to the circuit elements includes electrically separated branch portions. Each of the circuit elements includes a body portion disposed on the plane not to overlap the conductors and a pair of terminals extending from the body portion and electrically connected to the branch portions.

The present application is based on Japanese patent application No. 2013-010852 filed on Jan. 24, 2013, the entire contents of which are incorporated here in by reference.

### BACKGROUND OF THE INVENTION

1. Field of the Invention

The present invention relates to a flat wiring member and a manufacturing method thereof.

2. Description of the Related Art

A lithium-ion secondary battery module mounted in an electric vehicle or a hybrid vehicle has a structure in which a plurality of unit cells are disposed and electrode terminals of adjacent ones of the unit cells are connected by connecting members such as bus bars. A lithium-ion secondary battery has a risk of generating heat when overcharged, and is degraded in charging and discharging function owing to the dissolution of electrode material when overdischarged. Therefore, the lithium-ion secondary battery requires a voltage control with substantially high accuracy on the order of tens of millivolts. Therefore, the bus bars connected to the cells are connected to a control circuit and a protection circuit via a wiring member for monitoring the potential of respective electrodes.

Given the size of the secondary battery module, the length of the wiring member for voltage monitoring ranges from approximately 0.5 m to approximately 1 m. Further, since the wiring distance between a circuit board and the bus bars is different among the bus bars, the wiring member includes a plurality of conductors and forms an arbitrary wiring pattern in which the conductors branch from the bundle of conductors.

In the past, a wire harness has been used as the wiring member for voltage monitoring. Since the wire harness has a structure including a plurality of cables for the connection of electrodes, a process of binding the plurality of cables together is complicated. Further, to incorporate a current fuse into the wire harness, an operation of connecting the current fuse and the wire harness needs to be performed by an operator.

Furthermore, due to a thick bundle of cables of the wire harness, the area occupied by the wiring member is increased. Moreover, the flexibility of the wire harness makes it difficult to position the cables to the electrodes.

Meanwhile, due to a demand for an increase in capacity of the lithium-ion secondary battery and a reduction in size thereof, the number of cells and wiring members has been increasing. However, there is also a demand for a reduction of the area occupied by the wiring member. Further, since wiring in an arbitrary pattern is required of the wiring member, a flat wiring member such as a flexible printed circuit (FPC) is used. With the use of a thin flat wiring member such as the FPC, it is possible to reduce the area occupied by the wiring member. Further, with the pattern of the wiring member previously formed into a shape fitting the respective positions of the bus bars, erroneous wiring is prevented in the assembling of the battery module, and an operation of positioning the flat wiring member and the bus bars for connection is simplified.

The FPC as an example of the flat wiring member is manufactured by a process of forming by photolithography a wiring pattern on a film substrate, which is a polyimide film serving as a covering member and bonded with copper foil, and removing unnecessary copper portions by etching.

In the FPC, the conductor pattern is formed by etching the copper foil, and thus a large amount of copper material is wasted. Further, materials other than for etching (photoresist, development solution, cleaning solution, and so forth) are required. Particularly in the case of a flat wiring member for voltage monitoring, if the wiring pattern has a simpler structure in which elongated conductors branch, unlike a complicated and high-density wiring pattern of an electronic circuit, a larger amount of material is wasted, increasing costs.

Further, in the case of existing flat wiring members, circuits having a size of tens of centimeters square are usually formed by photolithography. Meanwhile, the flat wiring member for voltage monitoring has a length of approximately 1 m, and thus is not processable by existing photolithography machines. Therefore, there arises a need to increase the size of the photolithography machines, and thus the costs for manufacturing the flat wiring member are further increased.

Meanwhile, a flat wiring member reducing the size of the FPC has been proposed as an existing technique addressing the above-described issues (see Japanese Unexamined Patent Application Publication No. 2002-203431, for example).

The flat wiring member includes a ribbon cable and an FPC. The ribbon cable serves as a first flat cable. The FPC serves as a second flat cable connected to an intermediate position of the first flat cable via a connecting member. Some of conductors of the first flat cable are electrically connected to some of conductors of the second flat cable.

### SUMMARY OF THE INVENTION

In the existing flat wiring member, however, the ribbon cable is incapable of forming a branching wiring structure. Thus, the flat wiring member is configured to connect the FPC to the ribbon cable, and a step of connecting the ribbon cable and the FPC is required. Therefore, there is an issue of complication of the manufacturing process of the flat wiring member.

Further, a current fuse for protecting the control circuit and so forth when an excessive amount of current flows from the cells or the like is required to be inserted in serial in the flat wiring member for voltage monitoring to save the space and reduce the number of components. The insertion of a circuit element such as the current fuse in the flat wiring member, however, poses an issue of an increase in thickness of the flat wiring member.

Accordingly, it is an object of the present invention to provide a flat wiring member and a manufacturing method thereof capable of suppressing an increase in thickness of the flat wiring member even if a circuit element is connected to the flat wiring member and simplifying a manufacturing process of the flat wiring member.

To achieve the above-described object, embodiments of the present invention provide a flat wiring member and a manufacturing method thereof described below.

According to a first aspect of the present invention, there is provided a flat wiring member including a plurality of conductors disposed on a plane to be spaced from one another and one or more circuit elements connected to one or more of the conductors. The conductors connected to the circuit elements each include a pair of electrically separated portions. The circuit elements each include a body portion disposed on the plane not to overlap the conductors and a pair of terminals extending from the body portion and electrically connected to the pair of electrically separated portions.

According to a second aspect of the present invention, in the flat wiring member according to the first aspect, the plurality of conductors may respectively include trunk portions disposed in parallel in a width direction of the conductors and branch portions to which the conductors branch from the trunk portions in the width direction or in a direction intersecting with the width direction.

According to a third aspect of the present invention, in the flat wiring member according to the second aspect, the branch portions may each include the pair of electrically separated portions.

According to a fourth aspect of the present invention, the flat wiring member according to the first aspect may further include a covering member that covers the conductors and the circuit elements with both end portions of the conductors exposed.

According to a fifth aspect of the present invention, the flat wiring member according to the third aspect may further include a first covering member that covers the trunk portions with end portions of the conductors on the side of the trunk portions exposed and a second covering member that covers the branch portions and the circuit elements with end portions of the conductors on the side of the branch portions exposed.

According to a sixth aspect of the present invention, there is provided a manufacturing method of a flat wiring member including the steps of: disposing a plurality of conductors on a plane to be spaced from one another; disposing respective body portions of one or more circuit elements on the plane not to overlap the conductors, and electrically connecting a pair of terminals extending from each of the body portions of the circuit elements to a pair of portions of each of one or more of the conductors, which are to be electrically separated from each other; and electrically separating the pair of portions.

According to a seventh aspect of the present invention, the manufacturing method of a flat wiring member according to the sixth aspect further includes the step of bending and branching the conductors in a width direction of the conductors or in a direction intersecting with the width direction from trunk portions of the conductors disposed in parallel in the width direction of the conductors to be spaced from one another, to thereby form branch portions.

According to the present invention, it is possible to suppress an increase in thickness of a flat wiring member even if a circuit element is connected to the flat wiring member, and simplify a manufacturing process of the flat wiring member.

### BRIEF DESCRIPTION OF THE DRAWINGS

FIG. 1 is a perspective view illustrating the exterior of a flat wiring member according to a first embodiment of the present invention.

FIG. 2 is a perspective view schematically illustrating a step of unwinding conductors from a reel.

FIG. 3 is a perspective view schematically illustrating a step of bending a conductor.

FIG. 4 is a perspective view schematically illustrating a branching state of the conductors.

FIG. 5 is a perspective view schematically illustrating a step of covering the conductors with a first covering member.

FIGS. 6A to 6C are perspective views schematically illustrating a step of connecting a circuit element to a conductor, FIG. 6A illustrating a step of disposing the circuit element on the conductor, FIG. 6B illustrating a step of electrically connecting terminals of the circuit element to the conductor, and FIG. 6C illustrating a step of separating the conductor.

FIG. 7 is a perspective view schematically illustrating a step of covering the conductors and circuit elements with second covering members.

FIG. 8 is a perspective view illustrating the exterior of a flat wiring member according to a second embodiment of the present invention.

FIG. 9 is a perspective view schematically illustrating a step of covering the conductors with a third covering member according to the second embodiment.

FIG. 10 is a perspective view schematically illustrating a step of removing removal portions of the third covering member according to the second embodiment.

### DETAILED DESCRIPTION OF THE PREFERRED EMBODIMENTS

With reference to the drawings, embodiments of the present invention will be described below. Throughout the drawings, constituent elements having substantially the same function are designated by the same reference numeral, and redundant description thereof will be omitted.

### SUMMARY OF EMBODIMENTS

Each of flat wiring members according to the present embodiments includes a plurality of conductors disposed on a plane to be spaced from one another and one or more circuit elements connected to one or more of the conductors. The conductors connected to the circuit elements each include a pair of electrically separated portions. The circuit elements each include a body portion disposed on the plane not to overlap the conductors and a pair of terminals extending from the body portion and electrically connected to the pair of electrically separated portions.

### First Embodiment

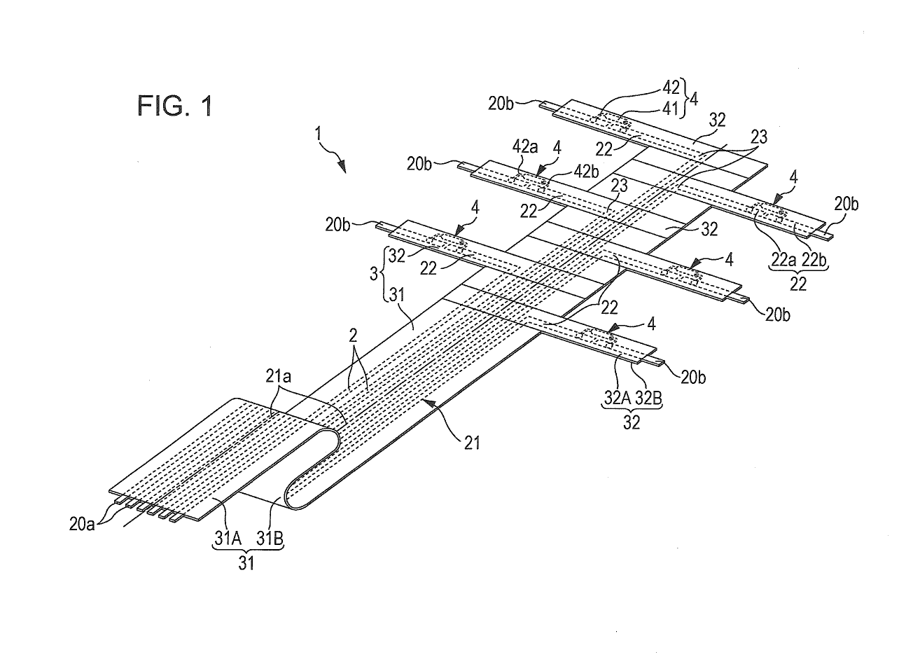

FIG. 1 is a perspective view illustrating the exterior of a flat wiring member 1 according to the embodiment of the present invention. The flat wiring member 1 includes a plurality (six in the present embodiment) of conductors 2 disposed on a plane to be spaced from one another, a plurality (six in the present embodiment) of circuit elements 4 respectively connected to the plurality of conductors 2, and a covering member 3 covering the conductors 2 and the circuit elements 4.

Conductors 2

Each of the conductors 2 includes a trunk portion 21 and a branch portion 22. The respective trunk portion 21 is extended in the longitudinal direction on the flat wiring member 1. The conductor 2 is bent and branches from the trunk portion 21 to the branch portion 22 in the width direction of the conductor 2 or in a direction intersecting with the width direction. The branch portion 22 is bent and branches starting from a branching portion 23. In this embodiment, the respective trunk portions 21 are disposed in parallel in the width direction of the conductors 2 to be spaced from one another. The branch portion 22 includes branch portions 22a and 22b, between which the conductor 2 is electrically separated. The branch portions 22a and 22b are an example of the pair of electrically separated portions.

The conductor 2 further includes end portions 20a and 20b and a branching portion 23. The end portion 20a is a portion of the trunk portion 21 exposed from the covering member 3. The end portion 20b is a portion of the branch portion 22 exposed from the covering member 3. At the respective branching portions 23, at least one conductor 2 branches (six conductors 2 branch in the present embodiment). The conductor 2 has a rectangular cross section having a width equal to or greater than the thickness thereof, for example. The conductor 2 may have a trapezoidal cross section or a cross section formed by an arc-shaped upper, lower, or side surface.

The trunk portion 21 is formed by a portion of the conductor 2 extending from the one end portion 20a to the branching portion 23. The branch portion 22 is formed by a portion of the conductor 2 extending from the branching portion 23 to the other end portion 20b. The branch portion 22 branches from the trunk portion 21 toward the outside of the trunk portion 21 not to overlap the other branch portions 22 and the trunk portions 21.

The branching portion 23 refers to a portion of the conductor 2 branching in a direction different from the direction of a centerline 21a. The centerline 21a is an imaginary line passing through toward the longitudinal center of the width direction of the first covering member 31. At the respective branching portions 23, the conductors 2 are bent in, for example, the width direction of the conductor 2, i.e., a direction at 90 degrees to the centerline 21a of the trunk portions 21, such that the respective end portions 20b are separated from the centerline 21a by the same distance. The angle at which the conductors 2 are bent at the branching portions 23 is not limited to 90 degrees. The conductors 2 may be bent in a direction intersecting with the width direction of the conductors 2, such as a direction at 45 degrees or 135 degrees, for example, to the centerline 21a of the trunk portions 21.

Oxygen free copper, tough pitch copper, copper alloy, aluminum, or nickel, for example, is employed as the material of the conductors 2. Further, the surfaces of the conductors 2 may be tin-plated.

Circuit Elements 4

Each of the circuit elements 4 includes a body portion 41 such as a current fuse and a pair of terminals 42 extending from the body portion 41. An element such as a current fuse, a temperature fuse, a resistor, a capacitor, or a diode, for example, is employed in the circuit element 4.

The body portion 41 of the circuit element 4 is disposed on the plane provided with the plurality of conductors 2 such that the body portion 41 does not overlap the conductors 2. The paired terminals 42 of the circuit element 4 are respectively electrically connected to the electrically separated branch portions 22a and 22b of the conductor 2. The terminals 42 of the circuit element 4 are respectively bent by bending portions 42a and 42b in a direction intersecting with the longitudinal direction of the conductor 2. In other portions than the bending portions 42a and 42b, the terminals 42 may be bent in the thickness direction of the conductor 2 to an extent that the resulting increase in thickness of the flat wiring member 1 does not pose a problem.

Covering Member 3

The covering member 3 includes a first covering member 31 and second covering members 32. The first covering member 31 covers the trunk portions 21 such that the end portions 20a of the conductors 2 on the side of the trunk portions 21 are exposed. The second covering members 32 cover the branch portions 22 and the circuit elements 4 such that the end portions 20b of the conductors 2 on the side of the branch portions 22 are exposed.

The first covering member 31 includes a pair of first covering members 31A and 31B, which cover the trunk portions 21 and parts of the branch portions 22 of the conductors 2 to expose the end portions 20a. The first covering member 31 covers the trunk portions 21 to thereby fix and insulate the conductors 2 as disposed in parallel.

The second covering members 32 each include a pair of second covering members 32A and 32B, which cover the branch portions 22 and the circuit elements 4 to expose the end portions 20b. Further, the second covering members 32 cover parts of the branch portions 22 and parts of the trunk portions 21 covered by the first covering member 31 such that these parts are doubly covered by the first covering member 31 and the second covering members 32. The second covering members 32 fix and reinforce the branch portions 22 and the circuit elements 4.

The first covering member 31 and the second covering members 32 are respectively bonded to the conductors 2 and the first covering member 31 in contact therewith by an adhesive applied to facing surfaces thereof. The first covering member 31 and the second covering members 32 may cover the trunk portions 21 and the branch portions 22 in accordance with a method such as fusion bonding.

An insulating material such as polyimide, polyamide, or polyethylene terephthalate, for example, is employed to form the first covering member 31 and the second covering members 32. As the adhesive, an epoxy-based adhesive or a polyester-based adhesive, for example, is employed. Covering members made of different materials and adhesives made of different materials may be employed to form the first covering member 31 and the second covering members 32.

Manufacturing Method of Flat Wiring Member 1

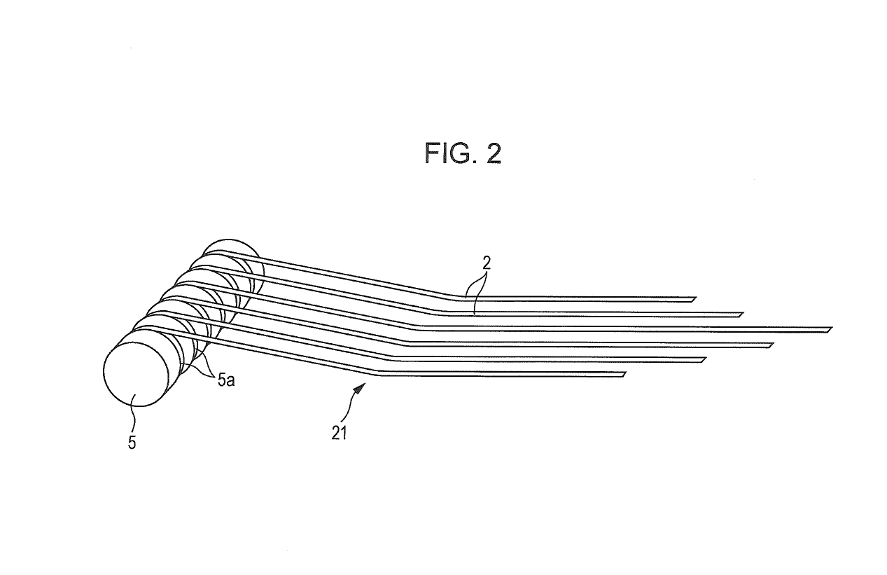

FIGS. 2 to 7 are diagrams illustrating an example of the manufacturing method of the flat wiring member 1. With reference to FIGS. 2 to 7, the example of the manufacturing method of the flat wiring member 1 will be described below in order of steps.

(1) Step of Supplying Conductors 2

FIG. 2 is a perspective view schematically illustrating a step of unwinding the conductors 2 from a reel 5. To manufacture the flat wiring member 1, the reel 5 is first prepared which includes a plurality of grooves 5a around which the conductors 2 are wound to be housed therein. The reel 5 having the conductors 2 wound therearound is held by not-illustrated holding members to be disposed parallel to the width direction of the conductors 2.

Then, as illustrated in FIG. 2, the plurality of conductors 2 are unwound from the reel 5 by a length necessary for bending the conductors 2. A plurality of different conducting materials may be housed in the reel 5, and the conductors 2 may be unwound from the reel 5 to manufacture the flat wiring member 1 including the different conducting materials.

(2) Step of Branching Conductors 2

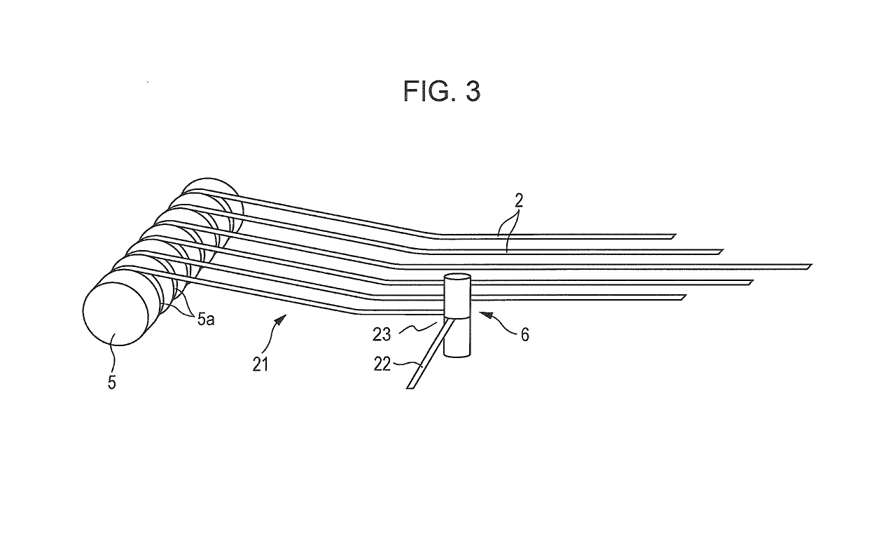

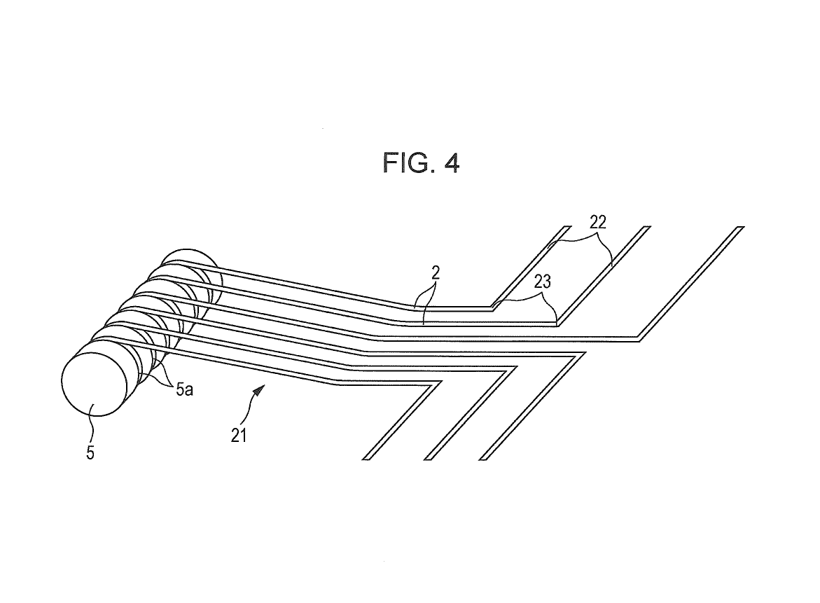

FIG. 3 is a perspective view schematically illustrating a step of branching the conductors 2. FIG. 4 is a perspective view schematically illustrating a branching state of the conductors 2. To branch the conductors 2, the supplied conductors 2 are bent by bending devices 6, as illustrated in FIG. 3. Each of the conductors 2 bent by the bending devices 6 branches from the trunk portion 21 of the conductor 2 in the width direction of the conductor 2 or a direction intersecting with the width direction, to thereby form the branch portion 22. The conductor 2 is branches starting from the branching portion 23. FIG. 3 illustrates only one of the bending devices 6.

Each of the plurality of conductors 2 is bent at a desired angle by the bending device 6 to have a shape including the trunk portion 21, the branching portion 23 and the branch portion 22, as illustrated in FIG. 4.

(3) Step of Covering with First Covering Member 31

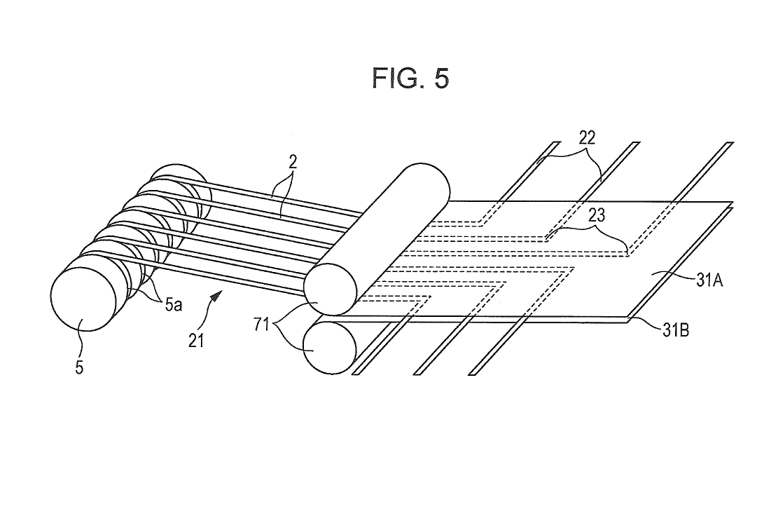

FIG. 5 is a perspective view schematically illustrating a step of covering the conductors 2 with the first covering member 31. To cover the trunk portions 21 of the conductors 2, a pair of rolls 71 is prepared around which the first covering members 31A and 31B are wound to be housed therein.

Then, as illustrated in FIG. 5, the first covering members 31A and 31B are unwound from the pair of rolls 71 while the conductors 2 are supplied from the reel 5. The paired first covering members 31A and 312 are then superimposed on each other to cover the trunk portions 21 and parts of the branch portions 22 with the end portions 20a of the conductors 2 exposed. The first covering member 31 may be folded back to cover the trunk portions 21 of the conductors 2.

As illustrated in FIG. 5, the pair of rolls 71 is held by not-illustrated holding members from the upper and lower sides of the conductors 2 to extend parallel to the width direction of the trunk portions 21.

(4) Step of Connecting Circuit Elements 4

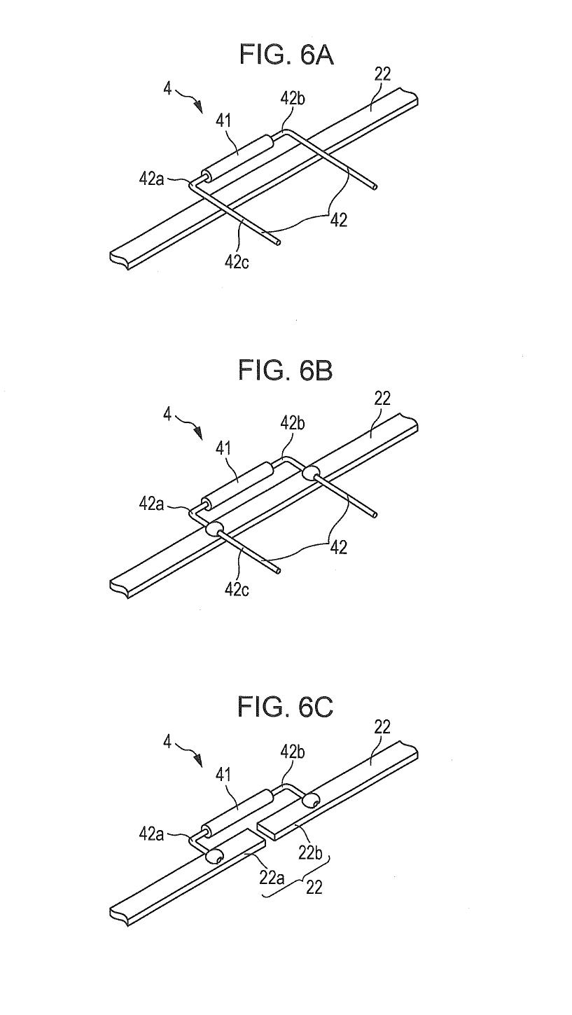

FIGS. 6A to 6C are perspective views schematically illustrating a step of connecting a circuit element 4 to a conductor 2. FIG. 6A illustrates a step of disposing the circuit element 4 on the conductor 2. FIG. 6B illustrates a step of electrically connecting the terminals 42 of the circuit element 4 to the conductor 2. FIG. 6C illustrates a step of separating the conductor 2.

To connect the circuit element 4 to the conductor 2, the paired terminals 42 of the circuit element 4 are bent at the bending portions 42a and 42b to form the circuit element 4 into a U-shape. Then, as illustrated in FIG. 6A, side surfaces 42c of the terminals 42 are brought into contact with the conductor 2, and the body portion 41 of the circuit element 4 is disposed on the plane provided with the plurality of conductors 2 such that the body portion 41 does not overlap the conductor 2.

Then, as illustrated in FIG. 6B, the pair of terminals 42 of the circuit element 4 is electrically connected to a pair of portions of the conductor 2, which are to be electrically separated from each other. The circuit element 4 and the conductor 2 are connected by soldering or welding, for example. Further, unnecessary portions of the terminals 42 closer to the end portions thereof than the portions thereof connected to the conductor 2 are removed.

Then, as illustrated in FIG. 6C, a portion of the conductor 2 located between the pair of terminals 42 of the circuit element 4 connected to the conductor 2 is electrically separated by a punching method using a die or an excision method using a cutter, laser, or the like. That is, the branch portion 22 of the conductor 2 is separated into the branch portions 22a and 22b.

(5) Step of Covering with Second Covering Members 32

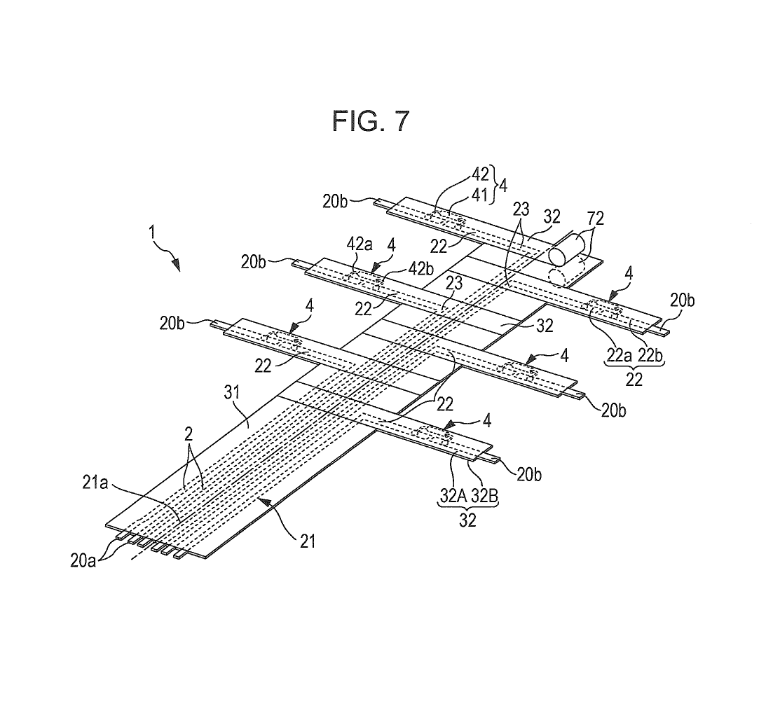

FIG. 7 is a perspective view schematically illustrating a step of covering the conductors 2 and the circuit elements 4 with the second covering members 32. To cover the branch portions 22 of the conductors 2 and the circuit elements 4, a pair of rolls 72 is first prepared around which the second covering members 32A and 32B are wound to be housed therein. As illustrated in FIG. 7, the pair of rolls 72 is held by not-illustrated holding members from the upper and lower sides of the conductors 2 to extend parallel to a direction along the centerline 21a of the first covering member 31.

Then, as illustrated in FIG. 7, the second covering members 32A and 32B are unwound from the pair of rolls 72 in a direction perpendicular to the centerline 21a of the first covering member 31. The paired second covering members 32A and 32B are then superimposed on each other to cover the branch portions 22 and the circuit elements 4 with the end portions 20b of the conductors 2 exposed. Further, the second covering members 32A and 32B cover parts of the branch portions 22 and parts of the trunk portions 21 such that these parts are doubly covered by the first covering members 31A and 31B and the second covering members 32A and 32B. The second covering members 32 may be folded back to cover the branch portions 22 of the conductors 2 and the circuit elements 4.

### Effects of First Embodiment

The present embodiment has the following effects.

(A) With the circuit elements 4 disposed on the plane provided with the plurality of conductors 2 such that the body portions 41 of the circuit elements 4 do not overlap the conductors 2, it is possible to suppress an increase in thickness of the flat wiring member 1 even if the circuit elements 4 are connected to the flat wiring member 1.

(B) With the circuit elements 4 covered by the second covering members 32, it is possible to fix and insulate the circuit elements 4. Accordingly, it is possible to suppress disconnection and separation of the terminals 42 of the circuit elements 4.

(C) With the circuit elements 4 connected to the branch portions 22 of the conductors 2, which are widely spaced from one another, it is possible to suppress short circuit between the circuit elements 4 or between the circuit circuits 4 and the conductors 2. Connection of the large-sized circuit elements 4 is also possible.

(D) With the conductors 2 separated into the electrically separated portions after the connection of the circuit elements 4 to the branch portions 22 of the conductors 2, it is possible to suppress misalignment of the branch portions 22a and 22b in the process of separating the conductors 2. Accordingly, it is possible to suppress short circuit between the conductors 2.

(E) With the circuit elements 4 connected to the branch portions 22 of the conductors 2 after the covering of the trunk portions 21 of the conductors 2 with the first covering member 31, the trunk portions 21 are fixed by the first covering member 31. It is therefore possible to better suppress the misalignment of the branch portions 22a and 22b in the process of electrically separating the conductors 2.

(F) With the conductors 2 bent by the bending devices 6, it is possible to omit a step of connecting the trunk portions 21 and the branch portions 22. It is therefore possible to simplify the manufacturing process of the flat wiring member 1.

(G) With the conductors 2 unwound from the reel 5 and branched by the bending devices 6 to manufacture the flat wiring member 1, it is possible to omit an etching process from the manufacturing process of the flat wiring member 1, and thus simplify the manufacturing process of the flat wiring member 1. It is therefore possible to reduce the manufacturing costs of the flat wiring member 1. Further, the size of the flat wiring member 1 is not limited by the size of the photolithography machine used in the wiring pattern forming process. Accordingly, it is possible to easily manufacture the flat wiring member 1 having a desired length.

(H) With the first covering member 31 first covering the trunk portions 21 of the conductors 2, which are required to be parallel, accurate covering of the conductors 2 is possible. Accordingly, it is possible to manufacture the flat wiring member 1 with less insulation failures by a simple manufacturing process.

### Second Embodiment

While the first covering member 31 and the second covering members 32 separately cover the conductors 2 in the first embodiment, a third covering member 33 collectively covers the conductors 2 in the present embodiment. The following description will focus on features different from those of the first embodiment.

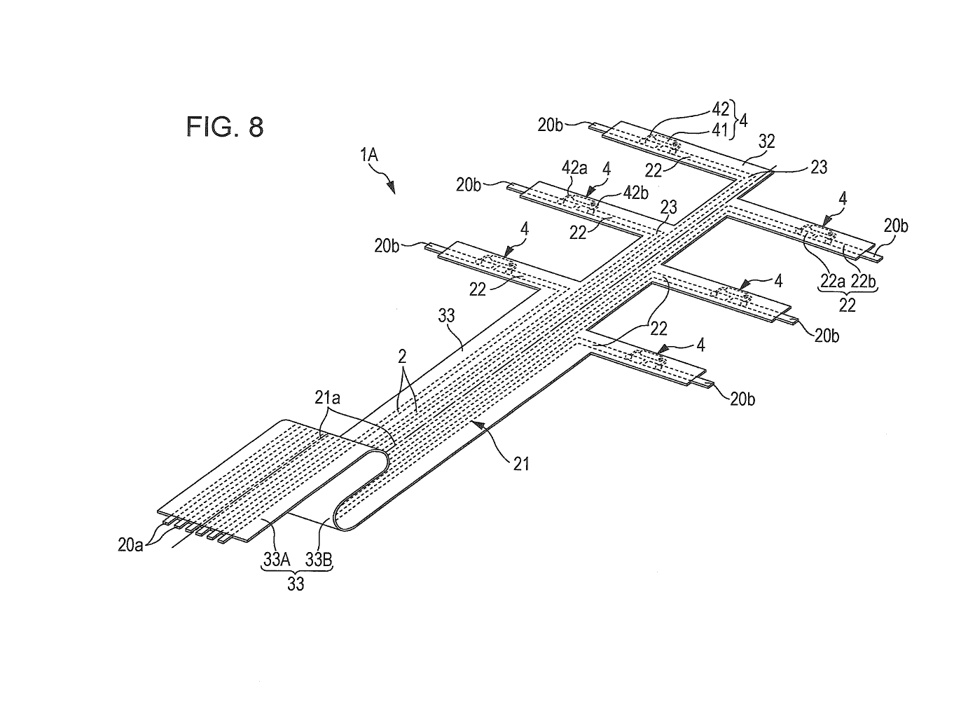

FIG. 8 is a perspective view illustrating the exterior of a flat wiring member 1A according to the second embodiment of the present invention. The third covering member 33 of the flat wiring member 1A according to the present embodiment includes a pair of third covering members 33A and 33B. In the third covering member 33, the paired third covering members 33A and 33B are superimposed on each other to cover the trunk portions 21 and the branch portions 22 of the conductors 2 and the circuit elements 4 with both the end portions 20a and 20b of the conductors 2 exposed. The third covering member 33 is bonded to the conductors 2 by an adhesive or the like applied to facing surfaces of the third covering member 33. The third covering member 33 is an example of the covering member.

Manufacturing Method of Flat Wiring Member 1A

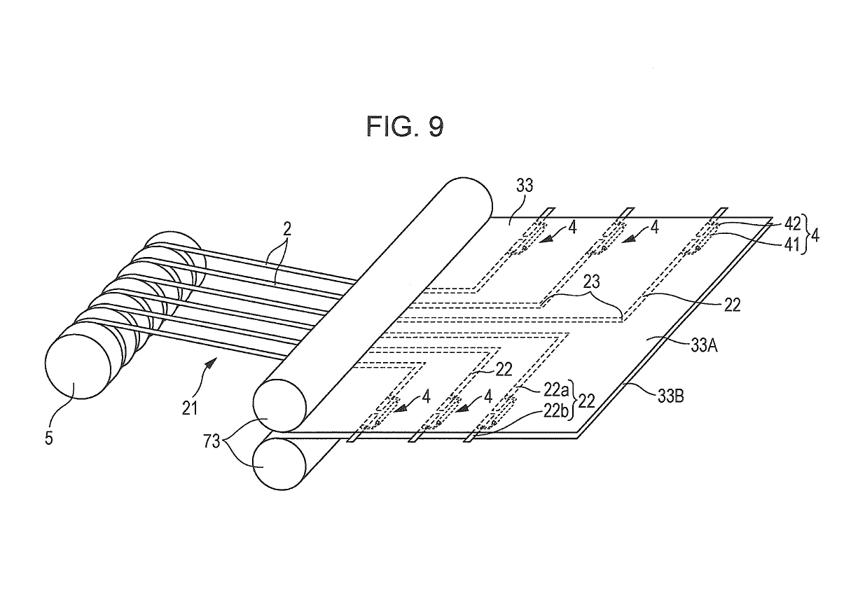

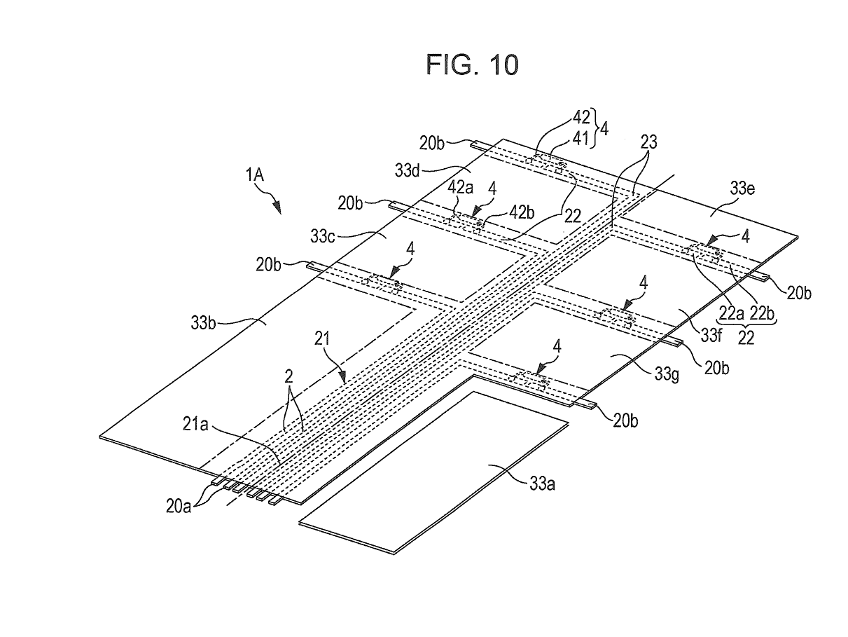

An example of the manufacturing method of the flat wiring member 1A will be described. FIG. 9 is a perspective view schematically illustrating a step of covering the conductors 2 with the third covering member 33 according to the second embodiment. FIG. 10 is a perspective view schematically illustrating a step of removing removal portions of the third covering member 33 according to the second embodiment.

To manufacture the flat wiring member 1A, the conductors 2 are bent by the bending devices 6, and thereafter the circuit elements 4 are connected to the branch portions 22 of the conductors 2. The branch portions 22 are separated into the branch portions 22a and 22b while the branching portions 23 are held by the bending devices 6. It is thereby possible to suppress the misalignment of the branch portions 22a and 22b.

Then, the conductors 2 and the circuit elements 4 are covered by the third covering member 33. To cover the conductors 2 and the circuit elements 4 with the third covering member 33, the third covering members 33A and 33B are unwound from a pair of rolls 73 while the conductors 2 are supplied from the reel 5, as illustrated in FIG. 9.

The unwound third covering members 33A and 33B are superimposed on each other in rectangular areas surrounded by the end portions 20a and 20b or by the end portions 20b, and cover the trunk portions 21 and the branch portions 22 of the conductors 2 and the circuit elements 4 with the end portions 20a and 20b of the conductors 2 exposed. The third covering member 33 unwound from a single roll 73 may be folded back to cover the trunk portions 21 and the branch portions 22 of the conductors 2 and the circuit elements 4.

Then, as illustrated in FIG. 10, removal portions 33a to 33g, in which the facing surfaces of the third covering member 33 are in contact with each other, are removed by a punching method using a die or an excision method using a cutter, laser, or the like, with margins for bonding left unremoved. FIG. 10 illustrates the removal of the removal portion 33a. The other removal portions 33b to 33g are also similarly removed.

### Effects of Second Embodiment

According to the present embodiment, it is possible to collectively cover the conductors 2 and the circuit elements 4 with the third covering member 33. Accordingly, it is possible to simplify the manufacturing process of the flat wiring member 1A.

### Modified Examples

Embodiments of the present invention are not limited to the above-described embodiments. The present invention may be modified or implemented in various ways within a scope not changing the gist of the present invention. For example, although the circuit elements 4 are covered by the second covering members 32 or the third covering member 33 in the above-described embodiments, the circuit elements 4 may be exposed from the covering members.

Further, each of the conductors 2 may have a linear shape not including the branch portion 22.

Further, the surfaces of the conductors 2 connected to the circuit elements 4 may have, for example, dents or the like to be connected to the terminals 42 of the circuit elements 4.

Further, the first to third covering members 31 to 33 are not necessarily unwound from the rolls, and may be previously cut in rectangular shapes to cover the conductors 2, the circuit elements 4, and so forth.

Further, although the branch portions 22 are formed on both sides of the trunk portions 21, the branch portions 22 may be formed only on one side of the trunk portions 21.

In the manufacturing methods according to the above-described embodiments, the addition, deletion, change in order, and replacement of steps are possible within a scope not changing the gist of the present invention. For example, the trunk portions 21 of the conductors 2 may be covered by the first covering member 31 after the connection of the circuit elements 4 to the conductors 2.

### INDUSTRIAL APPLICABILITY

The present invention is applicable to voltage monitoring wiring members, power transmission lines, signal lines, cellular phones, communication devices, information terminal devices, measuring devices, and household electrical appliances, for example.

What is claimed is:

1. A flat wiring member comprising:
a plurality of conductors disposed on a plane to be spaced from one another; and
one or more circuit elements connected to one or more of the conductors,
wherein the conductors connected to the circuit elements each include a pair of electrically separated portions, and
wherein the circuit elements each include a body portion disposed on the plane not to overlap the conductors and a pair of terminals extending from the body portion and electrically connected to the pair of electrically separated portions.

2. The flat wiring member according to claim 1, wherein the plurality of conductors respectively include trunk portions disposed in parallel in a width direction of the conductors and branch portions to which the conductors branch from the trunk portions in the width direction or in a direction intersecting with the width direction.

3. The flat wiring member according to claim 2, wherein the branch portions each include the pair of electrically separated portions.

4. The flat wiring member according to claim 1, further comprising:
a covering member that covers the conductors and the circuit elements with both end portions of the conductors exposed.

5. The flat wiring member according to claim 3, further comprising:
a first covering member that covers the trunk portions with end portions of the conductors on the side of the trunk portions exposed; and
a second covering member that covers the branch portions and the circuit elements with end portions of the conductors on the side of the branch portions exposed.

6. A manufacturing method of a flat wiring member comprising the steps of:
disposing a plurality of conductors on a plane to be spaced from one another;
disposing respective body portions of one or more circuit elements on the plane not to overlap the conductors, and electrically connecting a pair of terminals extending from each of the body portions of the circuit elements to a pair of portions of each of one or more of the conductors, which are to be electrically separated from each other; and
electrically separating the pair of portions.

7. The manufacturing method of a flat wiring member according to claim 6, further comprising the step of:
bending and branching the conductors in a width direction of the conductors or in a direction intersecting with the width direction from trunk portions of the conductors disposed in parallel in the width direction of the conductors to be spaced from one another, to thereby form branch portions.
